(19) United States
(12) Patent Application Publication
(10) Pub. No.: US 2013/0221218 A1
(43) Pub. Date: Aug. 29, 2013

(54) ELECTRON MICROSCOPE SYSTEM USING AUGMENTED REALITY

(71) Applicants: Jun-Hee LEE, Daejeon (KR); Yong-Ju KIM, Daejeon (KR)

(72) Inventors: Jun-Hee LEE, Daejeon (KR); Yong-Ju KIM, Daejeon (KR)

(21) Appl. No.: 13/748,183

(22) Filed: Jan. 23, 2013

(30) Foreign Application Priority Data
Feb. 27, 2012 (KR) 10-2012-0019690

(51) Int. Cl. H01J 37/26

(52) U.S. Cl. CPC H01J 37/261
USPC 250/310; 250/311

(57) ABSTRACT

Provided is an electron microscope system using an augmented reality in that it recognizes a sample identification information by using an observation image generated through an electron microscope and the observation image is linked with the pre-set sample information according to the recognized sample identification information, so that an augmented reality image thereof is provided, thereby even the unskilled man can easily utilize the electron microscope and it can generate excitement about an education thereof.

### CROSS REFERENCES

Applicant claims foreign priority under Paris Convention to Korean Patent Application No. 10-2012-0019690, filed Feb. 27, 2012, with the Korean Intellectual Property Office, where the entire contents are incorporated herein by reference.

### BACKGROUND OF THE INVENTION

1. Field of the Invention

The present invention relates to an electron microscope system using an augmented reality. More particularly, the present invention relates to an electron microscope system using an augmented reality in that it recognizes a sample identification information by using an observation image generated through an electron microscope and the observation image is linked with the pre-set sample information according to the recognized sample identification information, so that an augmented reality image thereof is provided, thereby even the unskilled man can easily utilize the electron microscope and it can generate excitement about an education thereof.

2. Description of the Prior Art

Generally, an electron microscope serves to observe a minute object by irradiating an electron beam on a sample and then using characteristics of an electron of reflecting from or penetrating the sample. Since the electron microscope can observe the sample at high magnifications over tens of thousands times in comparison with an optical microscope and have a high depth of focus, it is widely used in various inspection and analysis field.

There are a transmission electron microscope (TEM) and a scanning electron microscope (SEM) in the electron microscope.

The transmission electron microscope (TEM) includes an irradiating part, an imaging part, and an observing part. Thermions emitted from the irradiating part are focused by using the electronic lens and the focused electron beam penetrates the sample. Then, the penetrated electron beam is enlarged through the objective lens and the projection lens (electronic lens) and the image can be formed by means of a fluorescent screen installed in the observing part.

In the scanning electron microscope (SEM), the electronic beam fired from an electron gun is narrowly focused through the electronic lens to be irradiated on the surface of the sample and then, it detects the electrons emitted from the surface.

These electron microscopes have been utilized for the purpose of a research and development and a commerce in the country. In case of the advanced countries, since the electron microscopes are an optimum instrument of scientific curiosity, they are widely used in the science museum or the school for the purpose of science education.

However, the electron microscope is very expensive and it is necessary to search the coordinate of the sample and adjust the focus and magnification thereof for observing it. Accordingly, it is difficult for the observer, which is not familiar with the electron microscope, to use it. Also, in case of using the electron microscope for the purpose of the education, since the samples, which are observed at the high magnification, are not familiar to the general public, it is difficult to deliver enough educational contents.

Also, the electron microscope is used in various areas as well as a biology, a chemistry or a physics. That is, the teacher has an expert knowledge for his major, however, it is difficult for the teacher to have the expertise in the field of non-majors.

For example, a biology teacher has wide knowledge about the biology. However, since he can lack the expertise related to the minerals, it is difficult to deliver the explanation on the mineral samples to the student.

Likewise, owing to the complexity of the electron microscope operation and the expertise of the observation sample, it is difficult for the electron microscope to be used for educational purpose in a state that he is not trained enough for the professional knowledge.

### SUMMARY OF THE INVENTION

Accordingly, the present invention has been made to solve the above-mentioned problems occurring in the prior art, and an object of the present invention is to provide an electron microscope system using an augmented reality in that it recognizes a sample identification information by using an observation image generated through an electron microscope and the observation image is linked with the pre-set sample information according to the recognized sample identification information, thereby providing an augmented reality image.

Another object of the present invention is to provide an electron microscope system using an augmented reality in that the observation image is linked with a text information or image and sound information on the observation sample, so that even the unskilled man can easily utilize the electron microscope and it can generate excitement about an education thereof.

Further another object of the present invention is to provide an electron microscope system using an augmented reality in that it shows an explanation on the observation sample in a shape of an augmented reality, so that it can obtain an expert knowledge on the sample without an expertise on the observation sample.

In order to accomplish this object, there is provided an electron microscope system using an augmented reality, comprising:

an electron microscope for irradiating an electron beam on a standard sample and obtaining electron signals emitted from a surface of the standard sample or penetrating the standard sample;

an user interface for inputting an operating signal of an user so as to obtain the electron signals through the electron microscope;

a microcomputer for generating an observation image by using the electron signals detected through the electron microscope, generating a sample information for explanation of the sample corresponding to a plurality of points set in the standard sample, and generating an augmented reality image in that the generated sample information is added to the observation image, where the established point is located in the observation image through a moving of a stage thereof; and

a display unit for displaying the augmented reality image generated through the microcomputer on a monitor.

Preferably, the standard sample includes an identification mark and, where the identification mark is recognized in the generated observation image, the microcomputer serves to set a standard coordinate system based on a position information of the identification mark, calculate a moving distance and direction of the stage according to a moving direction and distance fixed through the standard coordinate system, and move the stage according to the calculated moving distance and direction, thereby generating the augmented reality image while automatically searching for the plurality of the points.

Preferably, a plurality of unit samples is formed in the standard sample and the microcomputer serves to calculate a moving order, a moving direction, and a moving distance of the stage according to fixed moving order, moving direction, and moving distance thereof, sequentially moving the stage according to the calculated moving order, moving direction, and moving distance thereof, sequentially search each unit sample, and generate the augmented reality image by connecting the observation image of each unit sample with the pre-set information of each unit sample.

Preferably, the microcomputer serves to move the stage according to an inputted signal during an input of the operation signal of the user and generate the augmented reality image corresponding a moved point, when a coordinate information of the moved point is coincided with the coordinate of the point established in the standard sample and the present magnification is coincided with the pre-set magnification.

Preferably, where the pre-set image is existed in the observation image, the microcomputer serves to generate an augmented reality image corresponding to the corresponding point by a pre-set magnification thereof.

Preferably, where an identification code information of the standard sample for observing target is inputted through the user interface, the microcomputer serves to determine the standard sample for observing target based on the identification code information of the standard sample, calculate a moving direction and distance of the stage according to a moving direction and distance fixed through a pre-set standard coordinate of the corresponding standard sample, and move the stage according to the calculated moving distance and direction, thereby generating the augmented reality image while automatically searching for the plurality of the points located in the standard sample.

Preferably, the microcomputer includes; a memory unit for storing any one among the sample information, coordinate and magnification information of the points for providing the sample information, and image and magnification information of the points for providing the sample information; an image recognizing unit for converting the electron signals detected through the electron microscope into image signals to generate the observation image and recognizing the unit sample and positions or images of the plurality of the points established in the unit sample from the generated observation image; and an image processing unit for connecting the sample information, which is pre-stored in the memory unit, with the observation image generated from the image recognizing unit based on the information recognized by the image recognizing unit to generate the augmented reality image.

### BRIEF DESCRIPTION OF THE DRAWINGS

The above and other objects, features and advantages of the present invention will be more apparent from the following detailed description taken in conjunction with the accompanying drawings, in which:

FIG. 1 is a block diagram illustrating an electron microscope system using an augmented reality according to the present invention;

FIG. 2 is a photograph view illustrating a standard sample of FIG. 1;

FIG. 3 is a flow chart illustrating an augmented reality providing method for electron microscope according to one embodiment of the present invention;

FIG. 4 is a flow chart illustrating an augmented reality providing method for electron microscope according to a second embodiment of the present invention;

FIG. 5 is a flow chart illustrating an augmented reality providing method for electron microscope according to a third embodiment of the present invention; and

FIG. 6 is a flow chart illustrating an augmented reality providing method for electron microscope according to a fourth embodiment of the present invention.

### DETAILED DESCRIPTION OF THE PREFERRED EMBODIMENTS

Hereinafter, an exemplary embodiment of the present invention will be described in detail with reference to the accompanying drawings.

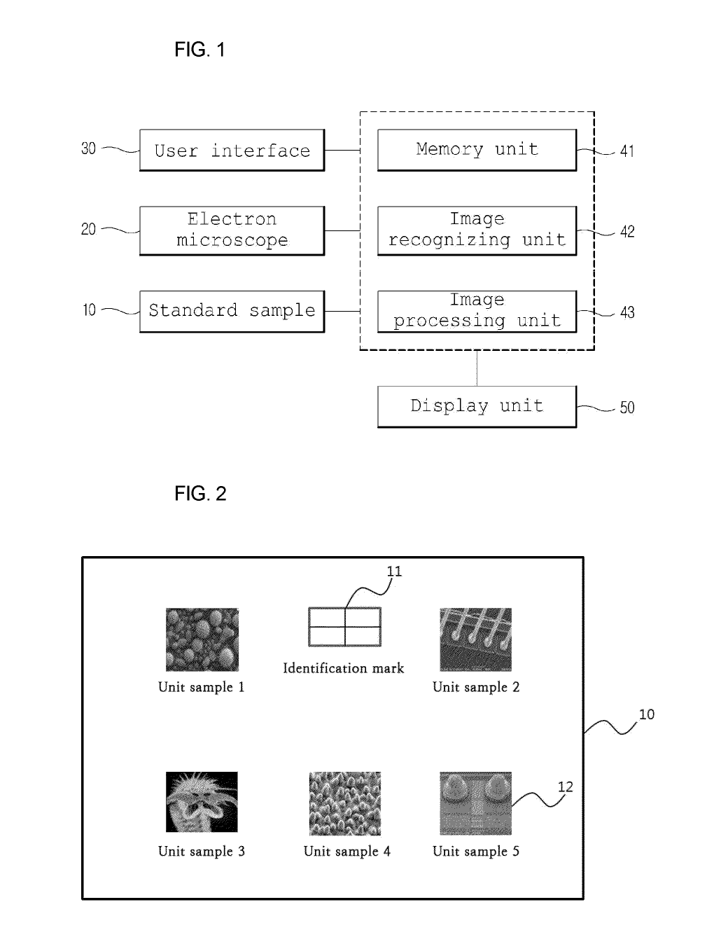

FIG. 1 is a block diagram illustrating an electron microscope system using an augmented reality according to the present invention and FIG. 2 is a photograph view illustrating a standard sample of FIG. 1.

Referring to FIG. 1 and FIG. 2, the electron microscope system using the augmented reality according to the present invention includes a standard sample 10, an electron microscope 20, an user interface 30, a microcomputer 40, and a display unit 50.

The standard sample 10 is placed on a stage of the electron microscope 20 so as to be observed through electron microscope 20. Here, the standard sample 10 includes an identification mark 11 for identifying the corresponding standard sample 10 and a plurality of unit samples 12 arranged on the periphery of the identification mark 11.

The electron microscope 20 serves to irradiate an electron beam on the standard sample 10 and obtain electron signals emitted from a surface of the standard sample 10 or penetrating the standard sample 10. Here, since the detailed construction on the electron microscope 20 is widely well-known in the art, further description on this is omitted here.

The user interface 30 serves to input an operating signal of the user so as to input a driving control signal of the electron microscope 20 for observing the sample. That is, the user interface 30 is an input unit such as a computer mouse or a computer keyboard. The user can input a moving direction and moving distance of the stage and a magnification information thereof and so on or directly input an identification code information of the standard sample 10 for observation by using the user interface 30. Here, the user can simply input the control signal of the stage by means of the user interface 30. However, actually the electron microscope 20 can be driven by a driving device of an X-axis, an Y-axis, an Z-axis, a T(tilt)X-axis, and a R(rotation)-axis for stage movement and focus adjustment etc.

The microcomputer 40 serves to generate an observation image by using the electron signals detected through the electron microscope 20, generate a sample information corresponding to a plurality of points set in the standard sample 10, and generate an augmented reality image in that the generated sample is added to the observation image. At this time, where the established point is located in the observation image or the pre-set image is existed in the observation image, the microcomputer 40 serves to generate an augmented reality image by a pre-set magnification thereof. Also, in order to the optimum observation image during generation thereof, the microcomputer 40 can take the focus according to the pre-set focus information or focus automatically in accordance with the characteristic of the corresponding unit sample 12.

At this time, the microcomputer 40 includes a memory unit 41, an image recognizing unit 42, and an image processing unit 43.

The memory unit 41 serves to store the sample information, a shape and a coordinate information of the identification mark 11 and the unit sample 12, coordinate and magnification information of the points for providing the sample information, image and magnification information of the points for providing the sample information, and the identification code information of the standard sample etc. Here, the sample information includes a text information for explaining the corresponding sample or a picture, an animation, and a sound information for illustration on the corresponding sample. Also, the memory unit 41 serves to store a search order having a starting point as the identification mark 11 for sequentially searching for the plurality of the points and the moving direction information and the moving distance information based on the search order. Moreover, the memory unit 41 serves to store a focus information on each unit sample so as to show the observation image on the unit sample 12 clearly.

The image recognizing unit 42 serves to convert the electron signals detected through the electron microscope 20 into image signals to generate the observation image and recognize the standard sample 10, the unit sample 12, and the identification information of the plurality of the points located in the unit sample 12 by recognizing positions or images on the identification mark 11, the unit sample 12, and the plurality of the points located in the unit sample 12 from the generated observation image.

The image processing unit 43 serves to add the sample information, which is pre-stored in the memory unit 41, to the observation image based on the information recognized by the image recognizing unit 42 to generate the augmented reality image. That is, the sample information such as the text of the sample, the picture, the animation, and the sound information is added to the observation image, thereby generating the augmented reality image.

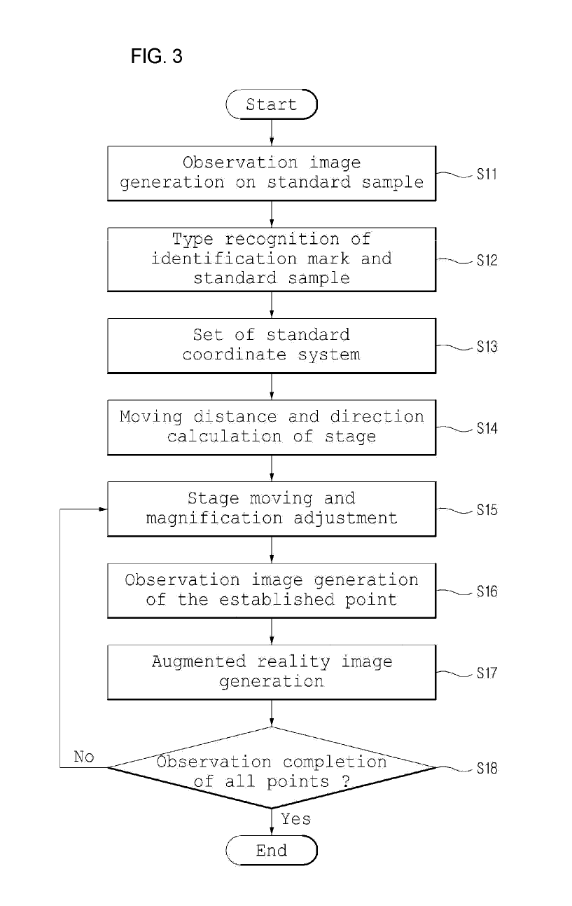

In the meantime, in the microcomputer 40, it is always set to an automatic mode during driving of the electron microscope 20 or it is set to the automatic mode when the automatic mode is selected through the operation of the user. At this time, the microcomputer 40 can sequentially search for the unit sample 12 or the plurality of the points based on a type recognition of the standard sample through the identification mark recognition, the moving order of the set stage, and the moving direction and magnification information, thereby providing the augmented reality image. Or, where the identification code information is inputted through the user, the microcomputer 40 can automatically search for the plurality of the points located in the standard sample 10 according to the driving signal established correspondingly to the identification code, thereby providing the augmented reality image. Or, the microcomputer 40 can manually search for the observation point according to the moving direction, the moving distance, and the magnification information inputted by the user. These operations will be described in detail with reference to the following FIG. 3 through FIG. 6.

Meanwhile, the display unit 50 serves to display the augmented reality image generated through the microcomputer 40 on a monitor. Also, the electron microscope system using the augmented reality according to the present invention can further include a speaker (not shown) for providing the sound information during providing the augmented reality image on the sample.

FIG. 3 is a flow chart illustrating an augmented reality providing method for electron microscope according to one embodiment of the present invention.

Hereinafter, the augmented reality providing method for electron microscope according to one embodiment of the present invention will be described in detail with reference to FIG. 1 and FIG. 2. At this time, one embodiment of the present invention corresponds to the automatic mode of automatically controlling the type recognition of the standard sample, the search of the plurality of the points located in the standard sample, and the unit sample 12, and the focus and the magnification thereof. That is, it is always set to the automatic mode during driving of the electron microscope 20 or it is set to the automatic mode when the automatic mode is selected through the operation of the user. Moreover, the present invention provides the augmented reality image while automatically searching for the unit sample 12 or the plurality of the points. Hereinafter, the unit sample or the plurality of the points will be commonly called “the plurality of the points”.

Firstly, the electron microscope 20 is driven, so that the observation image on the standard sample 11 is generated (S11). At this time, in order to the optimum observation image during generation thereof, the microcomputer 40 can take the focus according to the pre-set focus information and magnification information or focus and control the magnification automatically in accordance with the characteristic of each point established in advance.

Then, where the identification mark 11 is recognized in the generated observation image, it recognizes the type of the standard sample by using the type information of the identification mark 11 and so on (S12). Also, it sets the coordinate system based on the identification mark 11 by using the coordinate information of the plurality of the points established in advance (S13).

Continuously, it calculates the moving order fixed according to the type of the standard sample based on the coordinate system and the moving distance and direction of the stage based on the moving direction and the moving distance (S14). That is, it calculates the moving order, the moving direction, and the moving distance of the stage according to the relative distance and direction with the identification mark 11 based on the coordinate information of the identification mark 11 and the plurality of the pre-established points.

Thereafter, it allows the established point to be located at the observation area by driving the stage based on the moving direction, the moving distance, and the magnification information of the calculated stage (S15). Then, it generates the observation image of the established point (S16). At this time, in order to the optimum image on the unit sample, the stage can be driven by the driving device of the X-axis, the Y-axis, the Z-axis, the T(tilt)X-axis, and the R(rotation)-axis, which is formed in the electron microscope 20.

Continuously, the sample information of the pre-set point is added to the observation image of the unit sample, so that it generates the augmented reality image (S17).

Thereafter, the above steps S15˜S17 are repeated until the observation on the plurality of the points is completed according to the fixed order.

Here, according to the first embodiment of the present invention, it provides the augmented reality image on the corresponding unit sample while automatically searching for the plurality of the points. At this time, the image is sequentially provided without cutting off it during moving between each point, thereby providing the smooth augmented reality image.

Also, according to the first embodiment of the present invention, the observation images on the plurality of the points can be provided by the same magnification or by sequentially increasing or decreasing magnification.

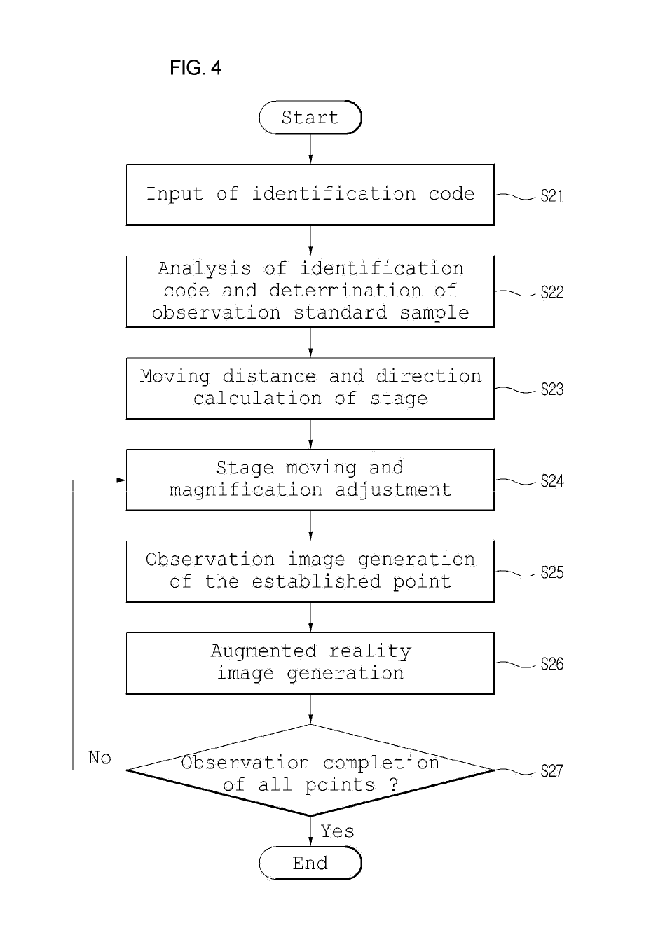

FIG. 4 is a flow chart illustrating an augmented reality providing method for electron microscope according to a second embodiment of the present invention.

Hereinafter, the augmented reality providing method for electron microscope according to the second embodiment of the present invention will be described in detail with reference to FIG. 1 and FIG. 2. At this time, in the second embodiment of the present invention, the search and the focus and magnification adjustment on the plurality of the points located in the standard sample are automatically implemented based on the identification code information inputted by the user.

Firstly, where the identification code is inputted through the user interface, it analyzes the inputted identification code and determines an observation standard sample among the standard samples established in the memory unit 41 based on the identification code information of the analyzed standard sample (S22).

Continuously, it calculates the moving distance and the moving direction based on the coordinate system established correspondingly to the corresponding standard sample and the fixed moving order information (S23).

Thereafter, it allows the established point to be located at the observation area by driving the stage based on the moving direction, the moving distance, and the magnification information of the calculated stage (S24). Then, it generates the observation image of the established point (S25).

Continuously, the sample information of the pre-set point is added to the observation image of the unit sample, so that it generates the augmented reality image (S26). Thereafter, the above steps S24˜S26 are repeated until the observation on the plurality of the points is completed according to the fixed order.

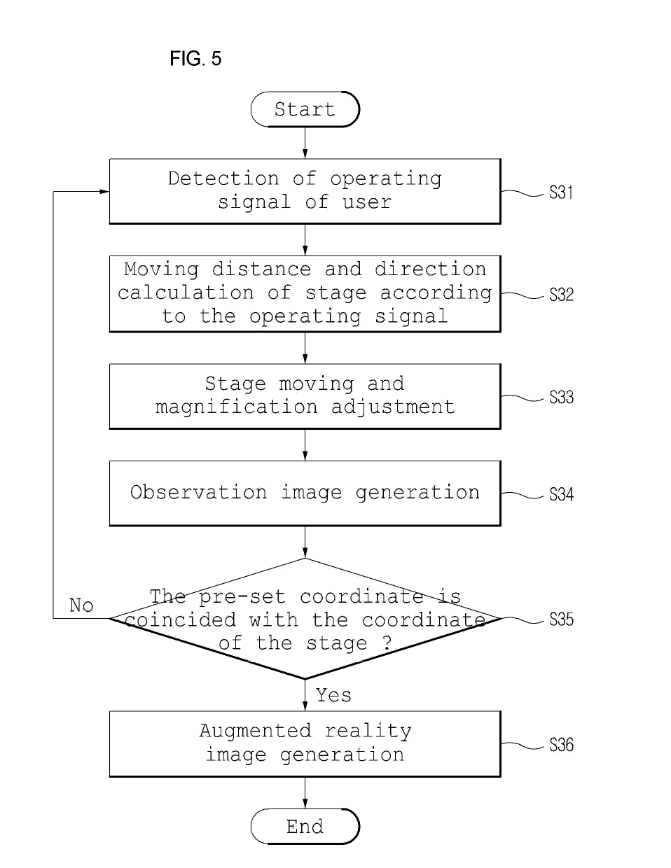

FIG. 5 is a flow chart illustrating an augmented reality providing method for electron microscope according to a third embodiment of the present invention.

Hereinafter, the augmented reality providing method for electron microscope according to the third embodiment of the present invention will be described in detail with reference to FIG. 1 and FIG. 2. At this time, in the third embodiment of the present invention, the search and the magnification adjustment on the unit sample are manually implemented according to the operation signal of the user.

Firstly, where the operation signal of the user is detected (S31), it calculates the moving distance and direction of the stage according to the inputted operation signal (S32).

Continuously, the stage is moved according to the calculated moving distance and direction of the stage and the magnification thereof is adjusted (S33), and then, it generates the observation image of the moved point (S34).

Thereafter, it compares as to whether the coordinate information of the moved point is coincided with the coordinate of the point established in the standard sample or not and it judges as to whether the present magnification is coincided with the pre-set magnification or not (S35). When they are coincided with each other, it generates the augmented reality image by connecting the observation image with the sample information corresponding to the corresponding point (S36).

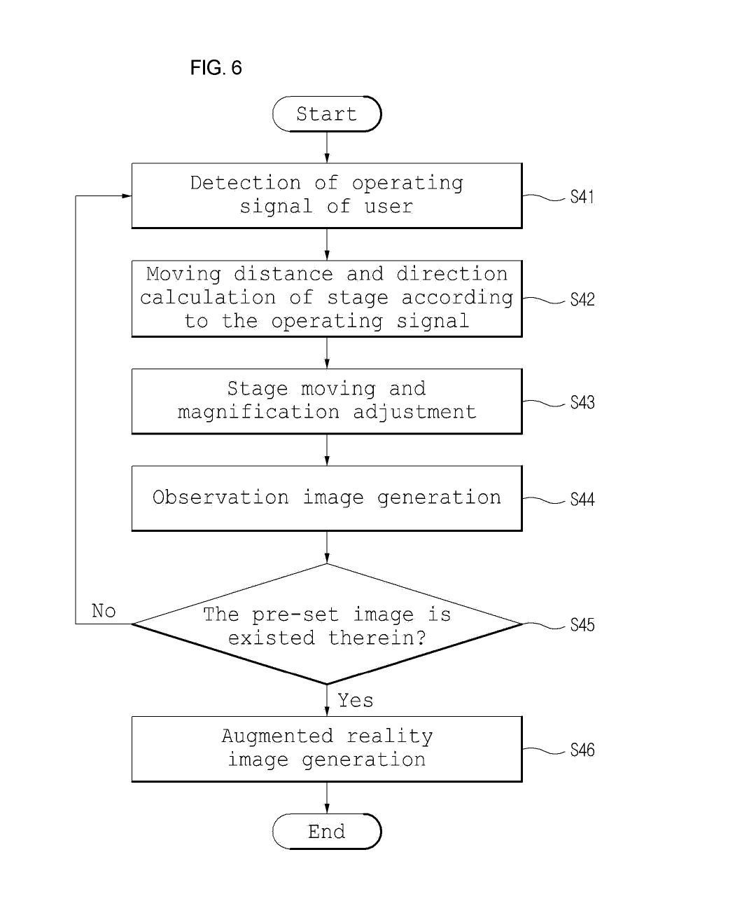

FIG. 6 is a flow chart illustrating an augmented reality providing method for electron microscope according to a fourth embodiment of the present invention.

Hereinafter, the augmented reality providing method for electron microscope according to the fourth embodiment of the present invention will be described in detail with reference to FIG. 1 and FIG. 2. At this time, in the fourth embodiment of the present invention, the search and the magnification adjustment on the unit sample are manually implemented according to the operation signal of the user.

Firstly, where the operation signal of the user is detected (S41), it calculates the moving distance and direction of the stage according to the inputted operation signal (S42).

Continuously, the stage is moved according to the calculated moving distance and direction of the stage and the magnification thereof is adjusted (S43), and then, it generates the observation image of the moved point (S44).

Thereafter, it analyzes the magnification information of the observation image and it judges that the magnification information corresponds to the pre-set magnification. At this time, where it is the pre-set magnification, it judges that the pre-set image is existed in the observation image (S45).

Then, when the image of the established point is existed in the observation image, it generates the augmented reality image by adding the observation image to the sample information of the corresponding point, which is pre-stored therein (S46).

Likewise, according to the embodiments of the present invention, it can recognize the established points by using the coordinate information of the specific points located in the observation images. Also, where the pre-set image is existed in the observation images, it can recognize the established points by using the image information.

Although a preferred embodiment of the present invention has been described for illustrative purposes, those skilled in the art will appreciate that various modifications, additions and substitutions are possible, without departing from the scope and spirit of the invention as disclosed in the accompanying claims.

What is claimed is:

1. An electron microscope system using an augmented reality, comprising:
an electron microscope for irradiating an electron beam on a standard sample and obtaining electron signals emitted from a surface of the standard sample or penetrating the standard sample;
an user interface for inputting an operating signal of an user so as to obtain the electron signals through the electron microscope;
a microcomputer for generating an observation image by using the electron signals detected through the electron microscope, generating a sample information for explanation of the sample corresponding to a plurality of points set in the standard sample, and generating an augmented reality image in that the generated sample information is added to the observation image, where the established point is located in the observation image through a moving of a stage thereof; and
a display unit for displaying the augmented reality image generated through the microcomputer on a monitor.

2. An electron microscope system using an augmented reality as claimed in claim 1, wherein the standard sample includes an identification mark and, where the identification mark is recognized in the generated observation image, the microcomputer serves to set a standard coordinate system based on a position information of the identification mark, calculate a moving distance and direction of the stage according to a moving direction and distance fixed through the standard coordinate system, and move the stage according to the calculated moving distance and direction, thereby generating the augmented reality image while automatically searching for the plurality of the points.

3. An electron microscope system using an augmented reality as claimed in claim 2, wherein a plurality of unit samples is formed in the standard sample and the microcomputer serves to calculate a moving order, a moving direction, and a moving distance of the stage according to fixed moving order, moving direction, and moving distance thereof, sequentially moving the stage according to the calculated moving order, moving direction, and moving distance thereof, sequentially search each unit sample, and generate the augmented reality image by connecting the observation image of each unit sample with the pre-set information of each unit sample.

4. An electron microscope system using an augmented reality as claimed in claim 1, wherein the microcomputer serves to move the stage according to an inputted signal during an input of the operation signal of the user and generate the augmented reality image corresponding a moved point, when a coordinate information of the moved point is coincided with the coordinate of the point established in the standard sample and the present magnification is coincided with the pre-set magnification.

5. An electron microscope system using an augmented reality as claimed in claim 1, wherein, where the pre-set image is existed in the observation image, the microcomputer serves to generate an augmented reality image corresponding to the corresponding point by a pre-set magnification thereof.

6. An electron microscope system using an augmented reality as claimed in claim 1, wherein, where an identification code information of the standard sample for observing target is inputted through the user interface, the microcomputer serves to determine the standard sample for observing target based on the identification code information of the standard sample, calculate a moving direction and distance of the stage according to a moving direction and distance fixed through a pre-set standard coordinate of the corresponding standard sample, and move the stage according to the calculated moving distance and direction, thereby generating the augmented reality image while automatically searching for the plurality of the points located in the standard sample.

7. An electron microscope system using an augmented reality as claimed in claim 3, wherein the microcomputer comprises;
a memory unit for storing any one among the sample information, coordinate and magnification information of the points for providing the sample information, and image and magnification information of the points for providing the sample information;
an image recognizing unit for converting the electron signals detected through the electron microscope into image signals to generate the observation image and recognizing the unit sample and positions or images of the plurality of the points established in the unit sample from the generated observation image; and
an image processing unit for connecting the sample information, which is pre-stored in the memory unit, with the observation image generated from the image recognizing unit based on the information recognized by the image recognizing unit to generate the augmented reality image.

8. An electron microscope system using an augmented reality as claimed in claim 4, wherein the microcomputer comprises;
a memory unit for storing any one among the sample information, coordinate and magnification information of the points for providing the sample information, and image and magnification information of the points for providing the sample information;
an image recognizing unit for converting the electron signals detected through the electron microscope into image signals to generate the observation image and recognizing the unit sample and positions or images of the plurality of the points established in the unit sample from the generated observation image; and
an image processing unit for connecting the sample information, which is pre-stored in the memory unit, with the observation image generated from the image recognizing unit based on the information recognized by the image recognizing unit to generate the augmented reality image.

9. An electron microscope system using an augmented reality as claimed in claim 5, wherein the microcomputer comprises;
a memory unit for storing any one among the sample information, coordinate and magnification information of the points for providing the sample information, and image and magnification information of the points for providing the sample information;
an image recognizing unit for converting the electron signals detected through the electron microscope into image signals to generate the observation image and recognizing the unit sample and positions or images of the plurality of the points established in the unit sample from the generated observation image; and
an image processing unit for connecting the sample information, which is pre-stored in the memory unit, with the observation image generated from the image recognizing unit based on the information recognized by the image recognizing unit to generate the augmented reality image.

10. An electron microscope system using an augmented reality as claimed in claim 6, wherein the microcomputer comprises;
a memory unit for storing any one among the sample information, coordinate and magnification information of the points for providing the sample information, and image and magnification information of the points for providing the sample information;
an image recognizing unit for converting the electron signals detected through the electron microscope into image signals to generate the observation image and recognizing the unit sample and positions or images of the plurality of the points established in the unit sample from the generated observation image; and
an image processing unit for connecting the sample information, which is pre-stored in the memory unit, with the observation image generated from the image recognizing unit based on the information recognized by the image recognizing unit to generate the augmented reality image.
